(19) United States
(12) Patent Application Publication
(10) Pub. No.: US 2019/0341881 A1
(43) Pub. Date: Nov. 7, 2019

(54) PHOTOVOLTAIC SOLAR ENERGY SYSTEM WITH RETRACTABLE MIRRORS

(71) Applicant: COMMISSARIAT A L'ENERGIE ATOMIQUE ET AUX ENERGIES ALTERNATIVES, Paris (FR)

(72) Inventors: Eric Pilat, Grenoble (FR); Franck Al Shakarchi, Grenoble (FR); José Ruben Sayritupac Vera, Grenoble (FR)

(21) Appl. No.: 16/401,632

(22) Filed: May 2, 2019

(30) Foreign Application Priority Data
May 4, 2018 (FR) 1853877

(51) Int. Cl. H02S 20/32; H02S 40/22; H02S 30/10; H01L 31/068

(52) U.S. Cl. CPC H02S 20/32; H01L 31/0684; H02S 30/10; H02S 40/22

(57) ABSTRACT

In order to limit the induced shading of the mirrors of a photovoltaic solar energy system, the latter comprises: a base structure, a rotating unit, and a rotation connection between the rotating unit and the base structure, the rotation connection defining a pivot axis of the rotating unit. At least one of the two mirrors is mobile by having a first end pivotably mounted on a structure sliding along an offsetting arm of the unit, the sliding structure able to be displaced between a high position bringing the mobile mirror into a configuration of maximum extent, and a low position bringing the mobile mirror into a configuration of minimum extent.

### CROSS-REFERENCE TO RELATED APPLICATIONS

This application claims priority from French Patent Application No. 18 53877 filed on May 4, 2018. The content of this application is incorporated herein by reference in its entirety.

### TECHNICAL FIELD

This invention relates to the field of photovoltaic solar energy, and in particular to systems comprising bifacial photovoltaic solar cells.

The invention applies in particular to systems intended to be installed on the ground or on roofs of buildings.

### PRIOR ART

From prior art, it is known to produce systems comprising photovoltaic solar cells with a bifacial nature, with these cells being grouped together within photovoltaic panels. The interest of such cells resides in the fact that they define two opposite absorption surfaces, for example on the front face a direct absorption surface intended to absorb solar radiation energy, and, on the rear face, an indirect absorption surface also intended to absorb solar radiation energy.

Several realisations have already been considered for obtaining this type of system. Document CN 204993212 is for example known, wherein is described systems provided with panels that comprise bifacial photovoltaic cells, extended downwards by reflectors. Each reflector is inclined in order to allow for the irradiation of the rear surface of the cells of another system located more to the front. This type of design nevertheless has many disadvantages, among which in particular the necessity of having a system engage with at least one other system located in the front, so as to illuminate its rear indirect absorption surface. The use of this type of system thus remains confined to solar power stations that have a plurality of rows of systems. In addition, the distance between each row becomes a parameter that depends on this need for irradiation of the rear surface by the systems of the rear row, in such a way that the space on the ground of the power station may be non-optimised. The same applies for the space along the vertical direction, due to the necessity of providing frames that are sufficiently raised to make it possible to install the reflectors at the bottom of the solar panels.

These same disadvantages are found on other systems, comprising two mirrors symmetrically arranged under the photovoltaic panels, in order to illuminate the indirect absorption surface thereof. Indeed, a vertical offset of these mirrors is required so as to authorise the amplitude in rotation required to follow the path of the sun, all throughout the day. In case of a vertical offset that is insufficient of the mirrors, the latter are able to limit the course of rotation of the rotating unit that comprises the photovoltaic panels and the mirrors, by interacting with the roof or with the ground on which the system rests. Furthermore, when the rotating unit is inclined on the side of one first of the two symmetrical mirrors in order to best direct its direct absorption surface with respect to a sun low in the sky, the second mirror is then in a position that generates a shadow that is detrimental for the directly consecutive system in the row of the solar power station concerned. In order to prevent this shading which is all the more so consequent when the sun is low, the systems of the same row can be spaced apart. However, this spacing of the systems generates a non-optimised rate of occupation of the ground or of the roof, with for consequence an energy potential that can be improved with respect to the square metres available.

### DISCLOSURE OF THE INVENTION

The invention therefore has for purpose to remedy at least partially the disadvantages mentioned hereinabove, concerning the realisations of prior art.

To do this, the invention first of all has for object a photovoltaic solar energy system comprising:

a base structure;

a rotating unit;

a rotation connection between the rotating unit and the base structure, the rotation connection defining a pivot axis of the rotating unit,

the rotating unit comprising:

a set of bifacial photovoltaic solar cells, jointly defining two opposite surfaces intended to absorb energy from solar radiation;

a support frame of said cells, the frame comprising at least one offsetting arm of the cells with respect to the base structure, a low end of the offsetting arm being connected to the rotation connection;

two mirrors each defining a reflector surface configured to reflect the light in the direction of the set of cells, preferably in the direction of an indirect absorption surface of this set, the two mirrors being arranged respectively on either side of the offsetting arm.

According to the invention, at least one of the two mirrors is mobile by having a first end pivotably mounted on a means sliding along the offsetting arm, the sliding means able to be displaced between a high position bringing the mobile mirror into a configuration of maximum extent, and a low position bringing the mobile mirror into a configuration of minimum extent wherein a second end of the mobile mirror, opposite the first end, is located closer to the offsetting arm than in the configuration of maximum extent.

Thus, the invention relates to a system with at least one of the two mirrors, and preferably both of them, having a retractable nature. Indeed, at the same as its first end is moving downwards along the offsetting arm, the mobile mirror tends to close with its second opposite end which approaches this same arm. Consequently, when the rotating unit is inclined on the side of one of the two mirrors, for example in order to best direct its direct absorption surface with respect to a sun low in the sky, the second mirror can then adopt the configuration of minimum extent or a configuration close to the latter, so as to limit the induced shading on the directly consecutive system in the row of the solar power station concerned.

The systems of the same row can then be brought closer to one another, as such optimising the occupation of the ground or of the roof, and consequently increasing the energy potential with respect to the square metres available. As an example, it has been determined that by implementing the principle of retractable mirrors on the systems of a row of a solar power station, the number of systems within this row could be increased by at least 75%.

Furthermore, the mirror located on the side where the rotating unit is inclined can also be folded to limit the interactions with the ground or the roof. Therefore, the length of the offsetting arm of the rotating unit can be decreased, with for consequence a gain in terms of mass and vertical space, while still authorising the tracking of the sun all throughout the day.

The invention also provides the following optional characteristics, taken separately or in combination.

The support frame also comprises a frame fixed on a high end of the offsetting arm, and a connection device is provided between each mobile mirror and the frame of the support frame, this connection device comprising a member sliding along the mobile mirror, as well as a pivot member allowing for a rotation of the sliding member in relation to the frame.

Preferably, the frame is substantially parallel to the set of bifacial photovoltaic solar cells, the frame being interposed between the two mirrors and the set of cells.

The support frame also comprises a plurality of frameworks connecting the frame to the set of bifacial photovoltaic solar cells.

The mobile mirror defines an acute mirror inclination angle with a plane orthogonal to the set of bifacial photovoltaic solar cells, the acute mirror inclination angle being between 5 and 30° in the configuration of minimum extent, and between 65 and 80° in the configuration of maximum extent.

The two mirrors are mobile, and arranged to be displaced symmetrically or asymmetrically.

According to a possibility, the two mobile mirrors are arranged in such a way as to be displaced symmetrically, the first end of each one of them being pivotably mounted on the same means sliding along the offsetting arm.

According to another possibility, the two mobile mirrors are arranged in such a way as to be displaced asymmetrically, the first end of each one of them being pivotably mounted respectively on two separate means sliding along the offsetting arm.

The set of bifacial photovoltaic solar cells can be configured to be displaced laterally on the side of one of the two mirrors, and on the side of the other mirror. In this case, it is for example provided that the support frame comprises a device with a deformable parallelogram designed to laterally displace the set of bifacial photovoltaic solar cells. Alternatively, it can be a simple means of translation of the set of cells, without leaving the scope of the invention.

The system comprises also at least one first actuator of the rotation connection between the rotating unit and the base structure, as well as at least one second mobile mirror actuator, with the first actuator or actuators being separate from the second actuator or actuators.

Alternatively, the system comprises a common actuator that simultaneously controls the rotation connection between the rotating unit and the base structure, as well as each mobile mirror.

The invention also has for object a solar power station that comprises at least one row of photovoltaic solar energy systems such as the one described hereinabove, with the pivot axes of the rotating units belonging to the systems of the row considered, being parallel to each other.

The power station preferably comprises several rows of photovoltaic solar energy systems.

Finally, the invention has for object a method for controlling such a solar power station, implemented in such a way that during the course of a day, the rotating unit of the systems of each row is pivoted from an extreme morning position wherein the unit is inclined on the side of a first of the two mirrors, to an extreme evening position wherein the rotating unit is inclined on the side of one second of the two mirrors, passing through a vertical median position of the rotating unit, with the method also implemented in such a way that for at least one of the systems of at least one of the rows:

the first mobile mirror is displaced from its configuration of minimum extent to its configuration of maximum extent when the rotating unit is displaced from the extreme morning position to its vertical median position, and/or the first mobile mirror is displaced from its configuration of maximum extent to its configuration of minimum extent when the rotating unit is displaced from its vertical median position to the extreme evening position;

and/or

the second mobile mirror is displaced from its configuration of minimum extent to its configuration of maximum extent when the rotating unit is displaced from the extreme morning position to its vertical median position, and/or the second mobile mirror is displaced from its configuration of maximum extent to its configuration of minimum extent when the rotating unit is displaced from its vertical median position to the extreme evening position.

Other advantages and characteristics of the invention shall appear in the non-limiting detailed description hereinbelow.

### BRIEF DESCRIPTION OF THE DRAWINGS

This description will be given with regards to the accompanying drawings among which;

FIG. 1 shows a front view of a solar power station, showing one of the rows of systems each formed by a plurality of systems according to a preferred embodiment of the invention;

FIG. 2 is a perspective view of one of the systems shown in the preceding figure;

FIG. 3 shows a front view of that of the preceding figure, diagramming the operation of the system and with its rotating unit shown in a vertical median position;

FIG. 3a is a view similar to that of FIG. 3, according to an alternative embodiment;

FIG. 4 shows a front view of two systems arranged directly consecutively in the row, with these systems being shown with their rotating units in an extreme morning position;

FIG. 5 shows a view similar to the preceding one, and whereon the two systems are shown with their rotating units in an extreme evening position;

FIG. 6 shows a partial view of one of the two systems of the preceding figure, diagramming a particular functionality of the invention;

FIG. 7 shows a view similar to that of FIG. 5, with the systems having the form of another preferred embodiment of the invention; and

FIG. 8 shows a view similar to the preceding one, with the rotating units arranged in their extreme morning position.

### DETAILED DISCLOSURE OF PARTICULAR EMBODIMENTS

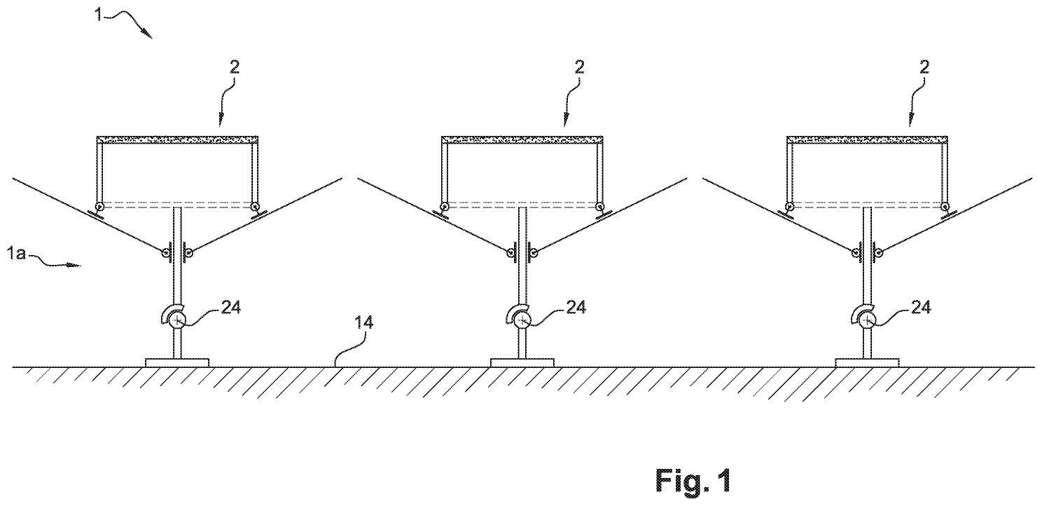

In reference first of all to FIG. 1, a solar power station 1 is shown that has a plurality of rows la, of which only a portion of one of these rows can be seen in the figure. Preferably, these rows are parallel to each other and each one comprises several photovoltaic solar energy systems 2, arranged side-by-side.

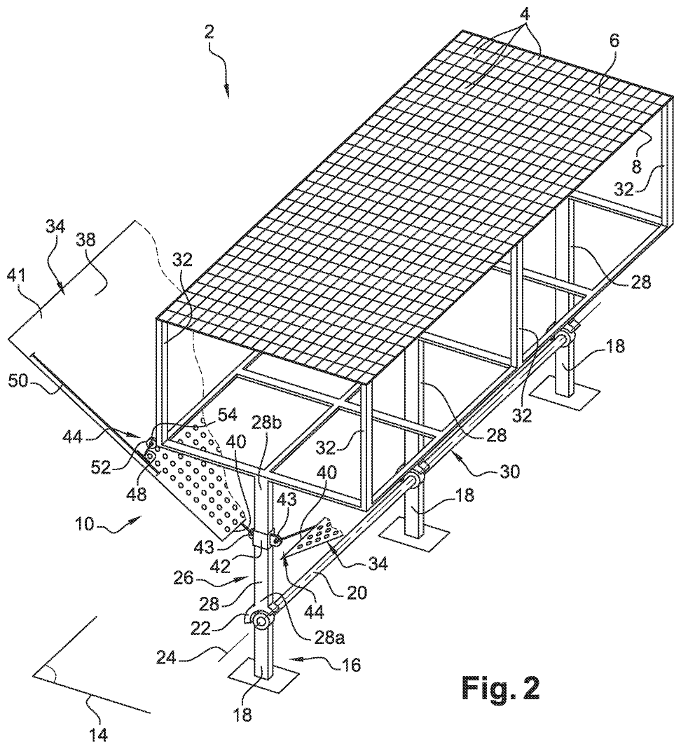

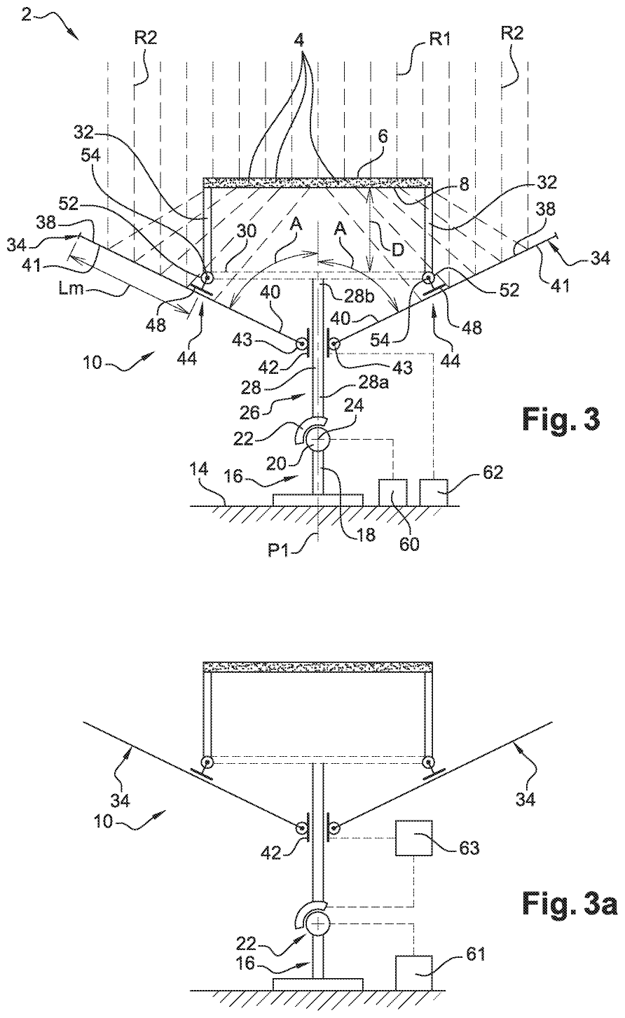

In reference to FIGS. 2 and 3, one of these systems 2 is shown, according to a preferred embodiment of the invention. In this respect, it is noted that all of the systems of the solar power station are identical or similar. These systems are fixed to the ground 14, each one using a base structure 16 that shall be described hereinafter. In other applications, one or several systems can be used so as to be arranged on a roof of a building.

In the embodiment of FIGS. 2 and 3, the system 2 first of all comprises a plurality of solar cells 4. These photovoltaic solar cells are of a bifacial nature, in such a way as to define together two opposite absorption surfaces. In this preferred embodiment, this is on the front face a direct absorption surface 6, and on the rear face, an indirect absorption surface 8. These two surfaces 6, 8 are conventionally substantially flat and parallel with one another, although another realisation could be considered by providing that these two surfaces are not parallel to one another. The solar cells 4 can be grouped together by panels, preferably all arranged substantially in the same plane.

The set of cells 4 is an integral part of a rotating unit 10, also known as a tracker. Other components are provided on this rotating unit 10, and shall be described hereinafter. The rotating unit 10 thus remains connected to the ground 14 using the base structure 16, carried out using several uprights 18 supporting a beam 20. The beam 20 is preferably of circular section, in such a way as to be able to install a rotation connection 22 between this beam 20 and the rotating unit. The rotation connection 22 defines a pivot axis 24 of the unit 10, with this axis 24 being preferably the one of the beam 20. In this respect, it is noted that the rotation connection 22 provides the unit 10 with the capacity to pivot relatively to the base structure 16, so as to be aligned with the sun all throughout the day. Thus, the pivot axis 24 is directed and inclined according to the latitude of the location of the systems 2. For example, for a latitude of 45.6° N, the pivot axis 24 can be oriented North-South, and inclined towards the south by an angle of about 30° in relation to the horizontal. This angle is frozen, or in another embodiment it can be controlled in order to constantly track, or in defined intervals of time, the change in the position of the sun in the sky during the course of the year. Within the same row la of the power station, the systems 2 have pivot axes 24 that are preferably parallel between them.

The rotating unit 10 also comprises a support frame 26 intended to support the panels of cells 4. This frame 26 first of all comprises one or several offsetting arms 28, arranged preferably orthogonally to the set of cells 4. These arms 28 are spaced apart from one another along the system 2, by falling for example in the same vertical plane as the uprights 18, when the unit 10 adopts its vertical median position such as shown in FIGS. 2 and 3. Here, each arm 28 is provided to vertically offset the cells 4 with respect to the base structure 16. A low end 28a of each arm 28 is connected to the rotation connection 22, even if alternatively, a plurality of separate and coaxial rotating connections 22 can be provided, each one associated to the low end 28a of an arm 28.

The high end 28b of each arm supports a frame 30 of the frame 26. This frame 30, parallel to the set of cells 4 and extending over a similar surface, is perforated to the maximum in order to allow for the passage of the rays reflected on the ground in the direction of the indirect absorption surface 8, such as shall be detailed hereinafter. It is conventionally formed by uprights and crosspieces, and it carries at its periphery a plurality of frameworks 32 connecting this frame to the set of cells 4. These frameworks 32 allow for an additional offsetting of the cells 4 with respect to the base structure 16.

Finally, the rotating unit 10 comprises two mirrors 34, which, in this preferred embodiment, both have a mobile nature within the unit. However, a single one of these two mirrors could be mobile and the other fixed, without leaving the scope of the invention.

The two mobile mirrors 34 are substantially flat, and arranged in such a way as to be displaced symmetrically in relation to a median plane P1 of the unit, wherein the offsetting arms 28 fall. The two mobile mirrors 34, arranged respectively on either side of the arms 28, as such that the frame 30 is vertically interposed between these mirrors and the cells 4. Together, they form a V of which the opening is controlled, as shall be detailed hereinafter. The two surfaces inside the V are reflector surfaces 38 configured to reflect the light in the direction of the indirect absorption surface 8 of the cells 4, such as diagrammed by the light rays R2 in FIG. 3. These reflected rays R2 contrast with the rays R1 which directly impact the direct absorption surface 6 of the cells, orthogonally to the latter as a front view.

The mobile mirrors 34 can be carried out by reflectors, for example used in the field of photography, rather than by more expensive mirrors used in the field of CPV (concentrated photovoltaics). The reflection coefficient can be with a range of 88-90%. By way of example, an aluminium plate can be used, about 1 mm thick, or a glass plate whereon is made a deposit of aluminium. According to a possibility, a reflective canvas can be used, for example a sheet of polymer of the PVF, PVDF, PET, etc. type, by using a frame with straps in order to maintain the flatness of reflector surface 38.

Each mobile mirror 34 has a first end 40 in the form of an edge parallel to the pivot axis 24, and which is pivotably mounted according to an axis 43 on at least one means 42 sliding along an offsetting arm 28. Preferably, a sliding means 42 can be provided on several of the arms 28, even over all of them. In this case, the edge 40 which forms the first end of the mirror 34 is pivotably mounted on each one of these sliding means 42, optionally using tabs coming from this edge 40 and forming an integral part of an axis pivot connection 43. In addition, it is preferably here arranged that on each offsetting arm 28 concerned, the sliding means 42 are common with the two mirrors 34, each one pivotably mounted on this means 42.

The first end 40 of each mirror 34 corresponds to its most inward edge within the rotating unit 10, and is therefore opposite a second free end 41 that corresponds to a parallel outer edge. Between these two ends 40, 41 of each mirror 34, the latter is connected to the periphery of the frame 30 by a connection device 44 of which the design allows the mirror to vary the inclination thereof, when its first end is displaced along the offsetting arms 28. More precisely, the connection device 44 comprises a member 48 sliding along the reflector surface 38 of the mobile mirror 34, for example in a rail 50 diagrammed in FIG. 2. The device 44 also comprises a pivot member 52 allowing for a rotation of the sliding member 48 in relation to the frame 30, according to an axis of rotation 54 parallel to the aforementioned axes 24, 43. It is noted that several connection devices 44 can be associated with each mobile mirror 34, for example by being distributed along the periphery of the frame 30, and by having confounded axes of rotation 54.

When the unit 10 adopts its vertical median position such as shown in the FIGS. 2 and 3, the sliding means 42 are in the high position on the vertical offsetting arm 28. In the front view shown in these figures, the arm 28 is vertically directed in relation to the ground 16, while the set of cells 4 is oriented horizontally. This position is adopted when the sun is at its highest in the sky, during the course of the day. It places the two mobile mirrors 34 into a configuration of maximum extent, wherein an acute angle of inclination A between the reflector surface 38 and the plane P1 is preferably between 65 and 80°, and more preferably between 70 and 75°. In this configuration of maximum extent, the second end 41 of each mirror is moved away from the offsetting arm 28. Each one of the two reflector surfaces 38 reflects the light rays R2 onto half of the indirect absorption surface 8 with the same incidence, implying that this surface 8 is illuminated uniformly over its entire surface area. This guarantees the best energy performance.

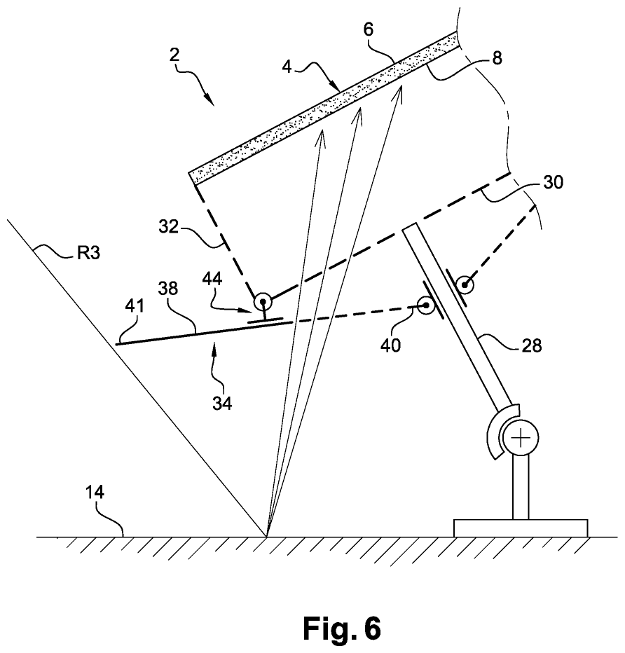

This configuration of maximum extent defines a maximum active width “Lm” of each mirror, with this width corresponding to the portion of the mirror protruding laterally from the frame 30. On the other hand, the other portion of the mirror located between the connection device 44 and the first end 40 remains inactive, and can optionally be non-reflective. However, the inactive portion is preferably perforated in such a way as to allow light rays R3 referenced in FIG. 6 to pass, so that the latter reflecting off the ground 14 can effectively pass through the mirror 34 then the frame 30, before impacting the indirect absorption surface 8. This radiation is all the more so substantial that the ground 14 has a reflective power, the ground thus being for example formed using white gravel. This radiation coming from the rays R3 is added to the radiation coming from the rays R2, shown in FIG. 2 and which reflect on the surface 38 of the mirrors.

In this same figure, several dimensions of the system are referenced, among which the maximum active width “Lm” of each mirror, preferably between 2 and 4.5 m. Furthermore, the separation distance “D” between the frame 30 and the indirect absorption surface 8 of the cells 4 is between 1 and 3 m.

The system 2 also comprises means for rotating the unit 10, and for varying the amplitude of the mirrors 34. To do this, in the embodiment described, a first actuator or a first group of actuators 60 is provided, making it possible to control the rotation connection 22 between the unit 10 and the base structure 16. The amplitude of rotation allowed by these first actuators 60, on either side of the vertical median position of FIG. 2, can be between 30 and 70°. Given that the concentration factor is low, the orientation precision of the unit 10 can be relatively rough (±3° instead of ±1° for CPVc). It therefore appears possible to use simple and robust actuators. It is thus not necessary to provide a magnetic position detection, which authorises for example the simple putting into series of “all or nothing” actuators, of the magnet or cylinder type.

The system 2 also comprises a second actuator or a second group of actuators 62, that make it possible to control the opening/the amplitude of the mobile mirrors 34. The actuators 62 make it possible to displace each sliding means 42 from bottom to top and from top to bottom, along the associated arm 28. This can for example be a linear motor, or a simple cylinder.

In this preferred embodiment, the first actuators 60 are separate from the second actuators 62. However, as the opening of the mirrors 34 is directly correlated with the inclination of the rotating unit about the pivot axis 24, these actuators 60, 62 are synchronised.

According to an alternative embodiment shown in FIG. 3a, an actuator or a group of common actuators 61 is provided that directly controls the rotation connection 22, between the unit 10 and the base structure 16. These actuators simultaneously control the opening of the mobile mirrors 34, through a movement transmission device 63 arranged between the rotation connection 22 and the sliding means 42. This transmission device 63 is more preferably a mechanical device, comprising conventional transmission members such as cams, connecting rods, endless screws, etc.

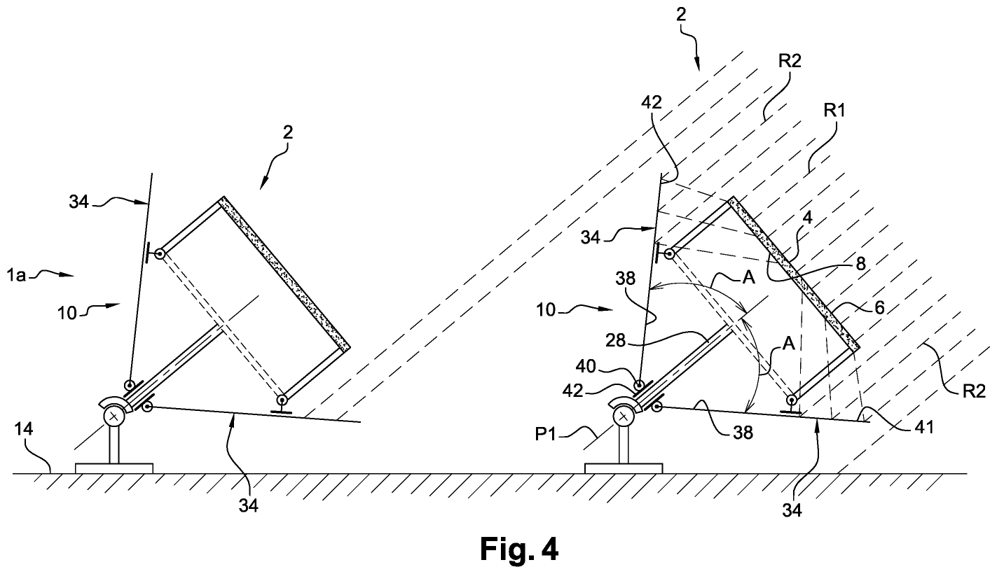

FIG. 4 shows two directly consecutive systems 2 within the same row, with their rotating units 10 in the extreme morning position, i.e. with the direct absorption surface 6 directed towards the east. In this position, the inclination of the unit 10 is maximal on the side of one first of the two mirrors 34, namely the one on the right in FIG. 4. The power station is preferably controlled in such a way that all of the systems 2 have their units 10 having the same inclination at every instant of the day.

Since this position is adopted in the morning when the sun is low, the two mirrors 34 then adopt a position of maximum extent, wherein the acute angle of inclination A between the reflector surface 38 and the plane P1 is preferably between 5 and 30°, although a higher value can be retained. In this configuration, the second end 41 of the two mirrors 34 is closer to the arm 28 and to the plane P1 than in the configuration of maximum opening.

In addition, in this configuration of minimum extent, each mirror 34 is lowered due to the displacement of its first end 40 downwards of the offsetting arm 28, via the sliding means 42 brought to the low position by the second actuators. Therefore, the shading induced by the second mirror 34, the farthest to the left in FIG. 4, is particularly low, and especially authorises a strong rapprochement of the directly consecutive system 2, which still guaranteeing that the latter has its mirrors 34 fully illuminated by the sun.

In this configuration, each one of the two reflector surfaces 38 reflects the light rays R2 on the other of the two surfaces 38, before these rays impact half of the indirect absorption surface 8 with the same incidence. In certain cases, the low opening of the mirrors could not allow for the illumination of the entire surface 8 using reflected rays R2. In this case, the illumination of the indirect absorption surface 8 would in any case be completed by the light rays R3, described hereinabove in reference to FIG. 6.

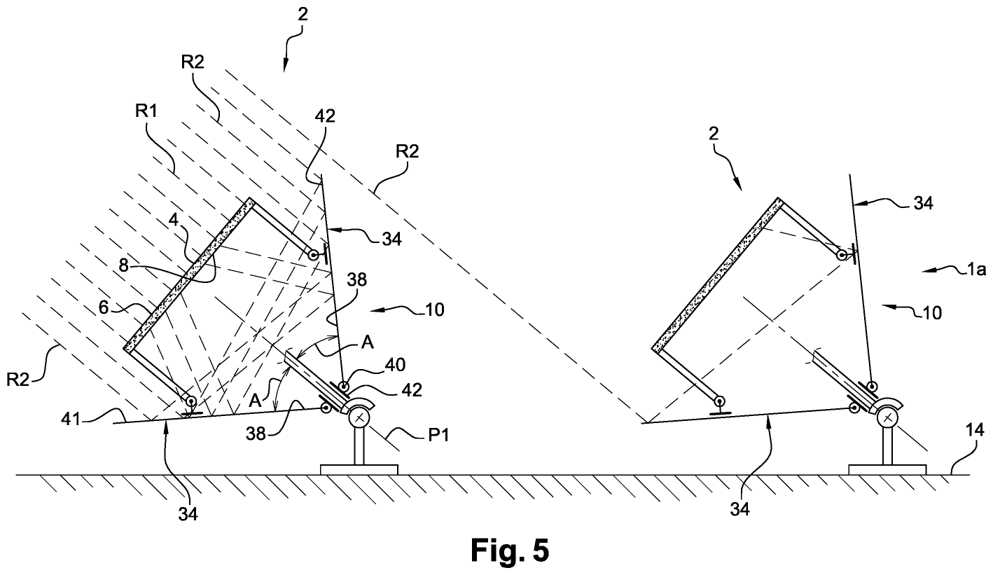

Thus, during the day, the systems 2 of each row la are controlled by the first actuators in such a way that their rotating units 10 are each pivoted from the extreme morning position of FIG. 4, to an extreme evening position shown in FIG. 5, symmetrically to the preceding one. In this extreme evening position, the rotating unit 10 is effectively inclined on the side of the second mirror 34, with its two mirrors again in the configuration of minimum extend. Because of this, the shading induced by the first mirror 34, the farthest on the right in FIG. 5, is particularly low, and above all authorises a strong rapprochement of the directly consecutive system 2, while still guaranteeing that the latter has its mirrors 34 fully illuminated by the sun.

Durant this displacement between the two aforementioned extreme positions, the rotating unit 10 transits through the vertical median position of FIG. 3. This daily displacement is accompanied by a controlling of the opening of the mirrors 34. In particular, it is provided that each one of the two mobile mirrors 34 be displaced from its configuration of minimum extent to its configuration of maximum extent, when the rotating unit 10 is displaced from the extreme morning position to its vertical median position. Then, it is provided that each one of the two mirrors 34 be displaced from its configuration of maximum extent to its configuration of minimum extent, when the rotating unit is displaced from its vertical median position to the extreme evening position. The displacement of the mirrors, via the second actuators, can take place linearly, or in stages of regular time intervals.

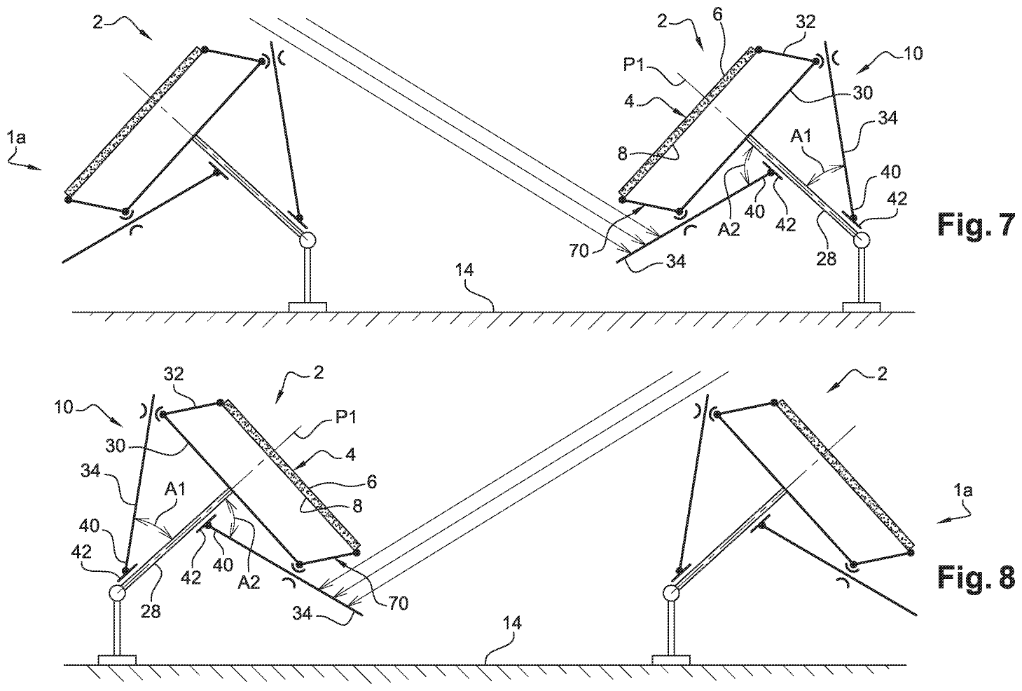

According to another embodiment shown in FIGS. 7 and 8, the two mirrors 34 are no longer controlled in such a way as to be displaced symmetrically with respect to the plane P1 passing through the offsetting arms 28, but they are to the contrary displaced asymmetrically. The first end 40 of each one of them is mounted on its own means 42 sliding along the arm 28, in such a way that the two means 42 are not necessarily at the same level on this arm. This is in particular the case in the extreme evening position shown in FIG. 7, wherein the first mirror 34, still on the right in the figure, resides in the configuration of minimum extent so as to limit the shading on the mirrors of the directly consecutive system 2. Inversely, the second mirror 34 adopts a configuration of higher extent, even maximum, allowing for a better illumination of the indirect absorption surface 8 of the cells 4, without being problematic with regards to the shading generated on the directly consecutive system. The two acute angles of inclination A1 and A2, respectively associated with the two mirrors 34, this have different values in the extreme evening position.

A similar situation is retained in the extreme morning position shown in FIG. 8, wherein the second mirror 34, still on the left in the figure, resides in the configuration of minimum extent so as to limit the shading on the mirrors of the directly consecutive system 2. Inversely, the first mirror 34 adopts a configuration of a higher extent, even maximum, allowing for a better illumination of the indirect absorption surface 8 of the cells 4, without being problematic with regards to the shading generated on the directly consecutive system.

During the daily rotation of the unit 10, the displacement control of the two mirrors 34 is adapted in such a way as to obtain the openings shown for the extreme positions in FIGS. 7 and 8, while still ensuring that they both adopt the configuration of maximum extent when the unit 10 is in the vertical median position in the middle of the day. Here again, a linear displacement or via stages can be adopted for the putting into movement of the two mirrors.

Finally, it is noted that in this preferred embodiment, or in the preceding one, the set of cells 4 is also provided to be laterally displaced on the side of the second mirror. More precisely, in the extreme evening position, the set of cells 4 is no longer symmetrical with respect to the plane P1, but transversally offset towards the side of the second mirror in order to limit the shading induced on the directly consecutive system 2.

Inversely, in the extreme morning position, the set of cells 4 is no longer symmetrical with respect to the plane P1, but transversally offset towards the side of the first mirror in order to limit the shading induced on the directly consecutive system 2. In other terms, during the daily rotation of the unit 10, an additional control allows for putting into motion the set of cells 4 in such a way that it is displaced from an extreme position on the side shown in FIG. 8, to an extreme position on the opposite side shown in FIG. 7, while still ensuring that it adopts a central position of symmetry with respect to the plane P1 when the unit resides in the vertical median position in the middle of the day.

In order to allow for this displacement of the set of cells 4, a simple translation connection is possible, but the implementing of a device 70 with a deformable parallelogram preferred. The frame 30 and the set of cells 4 then form two opposite sides of the parallelogram, while the frameworks 32 fulfil the function of the two other opposite sides of this parallelogram. For the actuating, one or several other actuators are implemented, or a specific translation movement device is retained, controlled by one or several other actuators of the system 2.

Of course, various modifications can be made by those skilled in the art to the invention which has just been described, solely by way of non-limiting examples. In particular, the characteristics of the various embodiments can be combined together. Furthermore, it is noted that the arrangement of the plane of the cells with respect to the frame is not limited to that of the examples described hereinabove, but this relative arrangement can be of any arrangement. The plane of the cells could thus be inclined by an angle different from 90° with respect to the plane of the offsetting arms 28. This angle could even be zero, leading to a parallelism or to an identity between the plane of the cells 4 and that of the arms 28. In this latter case, only one of the two reflector surfaces 38 of the two mirrors 34 is provided to reflect the light in the direction of the indirect absorption surface 8 of the cells 4, the other surface 38 being configured to reflect the light in the direction of the direct absorption surface 6.

1. Photovoltaic solar energy system (2) comprising:
a base structure (16);
a rotating unit (10);
a rotation connection (22) between the rotating unit (10) and the base structure (16), the rotation connection defining a pivot axis (24) of the rotating unit,
the rotating unit (10) comprising:
a set of bifacial photovoltaic solar cells (4), jointly defining two opposite surfaces intended to absorb energy from solar radiation;
a support frame (26) of said cells, the frame comprising at least one arm (28) for offsetting cells (4) with respect to the base structure (16), a low end of the offsetting arm (28) being connected to the rotation connection (22);
two mirrors (34) each defining a reflector surface (38) configured to reflect the light in the direction of the set of cells (4), preferably in the direction of an indirect absorption surface (8) of this set, the two mirrors being arranged respectively on either side of the offsetting arm (28),
characterised in that at least one of the two mirrors (34) is mobile by having a first end (40) pivotably mounted on a means (42) sliding along the offsetting arm (28), the sliding means (42) able to be displaced between a high position bringing the mobile mirror (34) into a configuration of maximum extent, and a low position bringing the mobile mirror (34) into a configuration of minimum extent wherein a second end (41) of the mobile mirror, opposite the first end, is located closer to the offsetting arm (28) than in the configuration of maximum extent.

2. System according to claim 1, wherein the support frame (26) also comprises a frame (30) fixed on a high end of the offsetting arm (28), and in that a connection device (44) is provided between each mobile mirror (34) and the frame (30) of the support frame, this connection device (44) comprising a member (48) sliding along the mobile mirror, as well as a pivot member (52) allowing for a rotation of the sliding member (48) in relation to the frame (30).

3. System according to claim 2,wherein the frame (30) is substantially parallel to the set of bifacial photovoltaic solar cells (4), the frame being interposed between the two mirrors (34) and the set of cells.

4. System according to claim 2, wherein the support frame (26) also comprises a plurality of frameworks (32) connecting the frame (30) to the set of bifacial photovoltaic solar cells (4).

5. System according to claim 1, wherein the mobile mirror (34) defines an acute mirror inclination angle (A) with a plane (P1) orthogonal to the set of bifacial photovoltaic solar cells (4), the acute mirror inclination angle (A) being between 5 and 30° in the configuration of minimum extent, and between 65 and 80° in the configuration of maximum extent.

6. System according to claim 1, wherein the two mirrors (34) are mobile, and arranged to be displaced symmetrically or asymmetrically.

7. System according to claim 6, wherein the two mobile mirrors (34) are arranged in such a way as to be displaced symmetrically, the first end (40) of each one of them being pivotably mounted on the same means (42) sliding along the offsetting arm (28).

8. System according to claim 6, wherein the two mobile mirrors (34) are arranged in such a way as to be displaced asymmetrically, the first end (40) of each one of them being pivotably mounted respectively on two separate means (42) sliding along the offsetting arm (28).

9. System according to claim 1, wherein the set of bifacial photovoltaic solar cells (4) is configured to be displaced laterally on the side of one of the two mirrors, and on the side of the other mirror.

10. System according to claim 9, wherein the support frame (26) comprises a device with a deformable parallelogram (70) designed to laterally displace the set of bifacial photovoltaic solar cells (4).

11. System according to claim 1, wherein it also comprises at least one first actuator (60) of the rotation connection (22) between the rotating unit (10) and the base structure (16), as well as at least one second mobile mirror actuator (62), with the first actuator or actuators being separate from the second actuator or actuators.

12. System according to claim 1, wherein it also comprises a common actuator (61) that simultaneously controls the rotation connection (22) between the rotating unit (10) and the base structure (16), as well as each mobile mirror (34).

13. Solar power station (1) comprising at least one row (1a) of photovoltaic solar energy systems (2) according to claim 1, with the pivot axes (24) of the rotating units (10) belonging to the systems of the row considered, being parallel to each other.

14. Power station according to claim 13, wherein it comprises several rows (1a) of photovoltaic solar energy systems (2).

15. Method for controlling a solar power station (1) according to claim 13, wherein during the course of a day, the rotating unit (10) of the systems (2) of each row is pivoted from an extreme morning position wherein the unit is inclined on the side of a first of the two mirrors (34), to an extreme evening position wherein the rotating unit (10) is inclined on the side of one second of the two mirrors (34), passing through a vertical median position of the rotating unit, and in that the method is implemented in such a way that for at least one of the systems (2) of at least one of the rows (1a):
the first mobile mirror (34) is displaced from its configuration of minimum extent to its configuration of maximum extent when the rotating unit (10) is displaced from the extreme morning position to its vertical median position, and/or in that the first mobile mirror (34) is displaced from its configuration of maximum extent to its configuration of minimum extent when the rotating unit (10) is displaced from its vertical median position to the extreme evening position;
and/or in that
the second mobile mirror (34) is displaced from its configuration of minimum extent to its configuration of maximum extent when the rotating unit (10) is displaced from the extreme morning position to its vertical median position, and/or in that the second mobile mirror (34) is displaced from its configuration of maximum extent to its configuration of minimum extent when the rotating unit (10) is displaced from its vertical median position to the extreme evening position.
